(19) United States
(12) Patent Application Publication
(10) Pub. No.: US 2008/0273414 A1
(43) Pub. Date: Nov. 6, 2008

(54) SEMICONDUCTOR DEVICE AND MEMORY CIRCUIT LAYOUT METHOD

(75) Inventors: Ming-Shiang Wang, Taoyuan County (TW); Wei-Li Liu, Taoyuan County (TW)

Correspondence Address: QUINTERO LAW OFFICE, PC, 2210 MAIN STREET, SUITE 200, SANTA MONICA, CA, 90405, US

(73) Assignee: NANYA TECHNOLOGY CORPORATION, TAOYUAN (TW)

(21) Appl. No.: 11/767,401

(22) Filed: Jun. 22, 2007

(30) Foreign Application Priority Data
May 1, 2007 (TW) TW96115460

(51) Int. Cl. G11C 8/12

(52) U.S. Cl. 365/230.03

(57) ABSTRACT

A memory comprising a memory array, a sensor amplifier, and a column driver/decoder. The memory comprises a plurality of memory cells. The sensor amplifier is disposed on one side of the memory array for accessing the memory cells of the memory array. The column driver/decoder is disposed on the opposite side of the memory array for selecting the memory cells of the memory array.

### BACKGROUND OF THE INVENTION

1. Field of the Invention

The invention relates to memory, and in particular to a column select line sharing structure memory.

2. Description of the Related Art

FIG. 1 is a structural diagram of conventional memory 100, comprising memory array 110, column driver/decoders 120, sensor amplifiers 130, data ports 140, and address ports 150. Memory array 110 comprises a plurality of memory cells. Each of column driver/decoder 120 is coupled between corresponding memory cells of memory array 110 and corresponding address ports 150. Each sensor amplifier 130 is coupled between corresponding memory cells of memory array 110 and corresponding data ports 140. With recent trends wherein capacity of memory becomes larger and memory becomes smaller, the number of circuit lines between column driver/decoder 120 and address ports 150 and between sensor amplifier 130 and data ports 140 increases and layout of the circuit lines becomes complicated.

### BRIEF SUMMARY OF THE INVENTION

A detailed description is given in the following embodiments with reference to the accompanying drawings.

An embodiment of a memory is provided. The memory comprises a memory array, a sensor amplifier and a column driver/decoder. The memory array comprises a plurality of memory cells. The sensor amplifier is disposed on one side of the memory array for accessing the memory cells of the memory array. The column driver/decoder is disposed on another side of the memory array for selecting the memory cells of the memory array.

Another embodiment of a memory is provided. The memory comprises a memory array, a plurality of sensor amplifiers, a plurality of column driver/decoders, a plurality of data ports, and a plurality of address ports. The memory array comprises a plurality of memory cells. The sensor amplifiers are disposed on one side of the memory array for accessing the memory cells of the memory array. The column driver/decoders are disposed on another side of the memory array for selecting the memory cells of the memory array. The data ports are disposed on one side near the sensor amplifiers. The address ports are disposed on another side near the column driver/decoders.

Another embodiment of a memory circuit layout method is provided. The method comprises locating a sensor amplifier on one side of the memory array and locating a column driver/decoder on the opposite side of the memory array.

Another embodiment of a semiconductor device is provided. The semiconductor device comprises a column select line sharing structure memory. The column select line sharing structure memory comprises a memory array, a plurality of sensor amplifiers, a plurality of column driver/decoders, a plurality of data ports and a plurality of address ports. The memory array comprises a first memory bank and a second memory bank, each of the first memory bank and the second memory bank comprising a plurality of memory cells. The sensor amplifiers are disposed on one side of the memory array for accessing the memory cells of the memory array. The column driver/decoders are disposed on the opposite side of the memory array for selecting the memory cells of the memory array. The data ports are disposed on one side near the sensor amplifiers. The address ports are disposed on another side near the column driver/decoders.

### BRIEF DESCRIPTION OF THE DRAWINGS

The invention can be more fully understood by reading the subsequent detailed description and examples with references made to the accompanying drawings, wherein:

FIG. 1 is a structural diagram of conventional memory;

FIG. 2 is a structural diagram of memory according to an embodiment of the invention;

FIG. 3 is a structural diagram of memory according to another embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

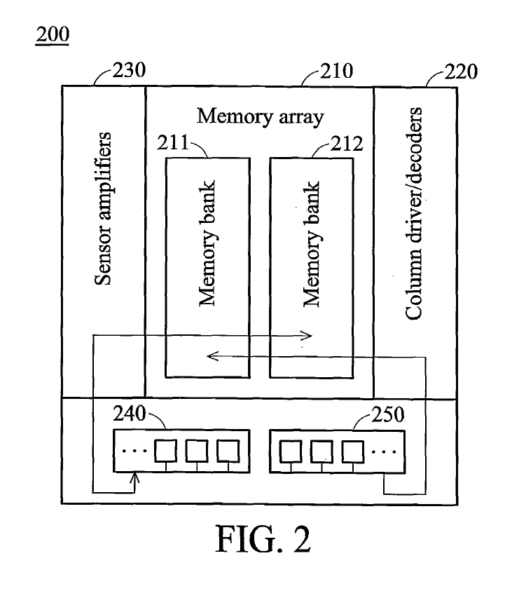

FIG. 2 is a structural diagram of memory 200 according to an embodiment of the invention. Memory 200 is a semiconductor device and can be manufactured by the semiconductor manufacturing process. Memory 200 may be a dynamic random access memory (DRAM). Memory 200 comprises memory array 210, a plurality of column driver/decoders 220, a plurality of sensor amplifiers 230, a plurality of data ports 240 and a plurality of address ports 250. As shown in FIG. 2, memory array 210 comprises memory banks 211 and 212. Each of memory banks 211 and 212 comprises a plurality of memory cells. Sensor amplifiers 230 are disposed on one side of memory array 210 for accessing memory cells of memory array 210. Column driver/decoders 220 are disposed on the opposite side or another side of memory array 210 for selecting memory cells of memory array 210. Data ports 240 are disposed on one side near sensor amplifier 230. Address ports 250 are disposed on another side near column driver/decoders 220.

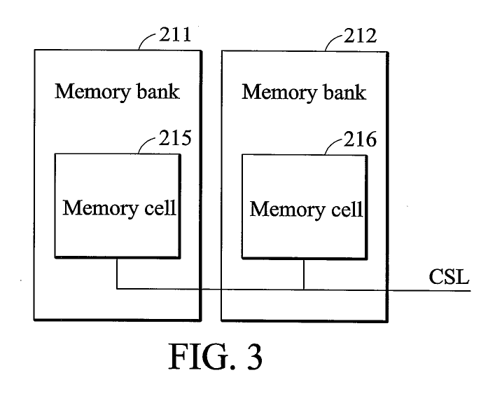

According to an embodiment of the invention, column driver/decoders 220 are disposed on one side of memory array 210 and sensor amplifiers 230 are disposed on the opposite side of memory array 210, reducing layout complication especially for a column select line sharing structure memory. With regard to the column select line sharing structure memory, at least two memory cells share a column select line (CSL), as shown in FIG. 3. One column select line CSL is in coupled to memory cells 215 and 216. Memory cell 215 is in memory bank 211, for example: Bank1. Memory cell 216 is in memory bank 212, for example: Bank2.

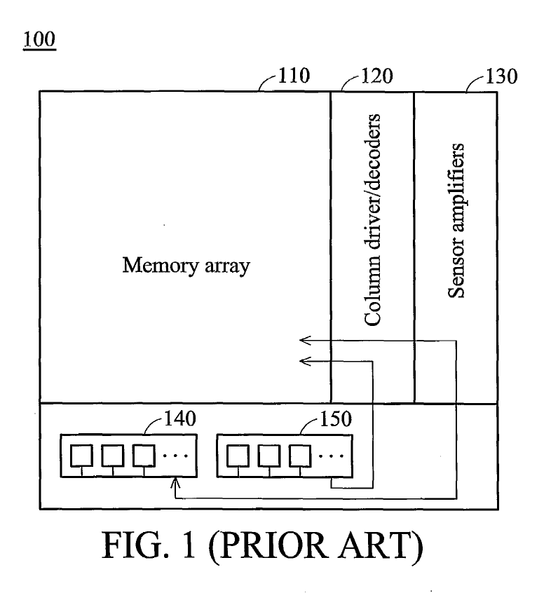

Conventionally, column driver/decoders 120 and sensor amplifiers 130 are disposed in the same side of memory array 110, as shown in FIG. 1. The circuit lines between column driver/decoder 120 and address ports 150 and the circuit lines between sensor amplifiers 130 and data ports 140 cross each other. Thus, the layout is complicated and difficult. According to the embodiment of the invention, column driver/decoders 220 are disposed on one side of memory array 210 and sensor amplifiers 230 are disposed on another side of memory array 210. The circuit lines between sensor amplifiers 230 and data ports 240 and the circuit lines between column driver/decoder 220 an d address ports 250 do not cross each other. This reduces layout complication and difficulty and further reduces memory layout area.

While the invention has been described by way of example and in terms of preferred embodiment, it is to be understood that the invention is not limited to thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
A memory, comprising:
a memory array comprising a plurality of memory cells;
a sensor amplifier disposed on one side of the memory array for accessing the memory cells of the memory array; and
a column driver/decoder disposed on another side of the memory array for selecting the memory cells of the memory array.

2. The semiconductor device as claimed in claim 1, wherein the column driver/decoder is disposed on the opposite side of the sensor amplifier.

3. The semiconductor device as claimed in claim 1, wherein the memory array further comprises at least one memory bank.

4. The semiconductor device as claimed in claim 3, wherein the memory bank comprises the memory cells.

5. The semiconductor device as claimed in claim 1, wherein the memory is a column select line sharing structure memory and at least two memory cells share a column select line.

6. The semiconductor device as claimed in claim 1, wherein the memory further comprises a plurality of data ports and address ports.

7. The semiconductor device as claimed in claim 6, wherein the data ports are disposed on one side near the sensor amplifier and the address ports are disposed on another side near the column driver/decoder.

8. A semiconductor device, comprising:
A memory, comprising:
a memory array comprising a plurality of memory cells;
a plurality of sensor amplifiers disposed on one side of the memory array for accessing the memory cells of the memory array;
a plurality of column driver/decoders disposed on another side of the memory array for selecting the memory cells of the memory array;
a plurality of data ports disposed on one side near the sensor amplifiers; and
a plurality of address ports disposed on another side near the column driver/decoders.

9. The semiconductor device as claimed in claim 8, wherein the column driver/decoders are disposed on the opposite side of the sensor amplifier.

10. The semiconductor device as claimed in claim 8, wherein the memory array further comprises at least one memory bank.

11. The semiconductor device as claimed in claim 10, wherein the memory bank comprises the memory cells.

12. The semiconductor device as claimed in claim 8, wherein the memory is a column select line sharing structure memory and at least two memory cells share a column select line.

13. A memory circuit layout method for a memory with at least one memory array, comprising:
locating a sensor amplifier on one side of the memory array; and
locating a column driver/decoder on the opposite side of the memory array.

14. The memory circuit layout method as claimed in claim 13, wherein the memory array further comprises at least one memory bank.

15. The memory circuit layout method as claimed in claim 14, wherein the memory bank comprises the memory cells.

16. The memory circuit layout method as claimed in claim 13, wherein the memory is a column select line sharing structure memory and at least two memory cells share a column select line.

17. The memory circuit layout method as claimed in claim 13, wherein the memory further comprises a plurality of data ports and address ports.

18. The memory circuit layout method as claimed in claim 17, further comprising locating the data ports on one side near the sensor amplifier and locating the address ports on another side near the column driver/decoder.

19. A semiconductor device, comprising:
A column select line sharing structure memory, comprising:
a memory array comprising a first memory bank and a second memory bank, each of the first memory bank and the second memory bank comprising a plurality of memory cells;
a plurality of sensor amplifiers disposed on one side of the memory array for accessing the memory cells of the memory array;
a plurality of column driver/decoders disposed on the opposite side of the memory array for selecting the memory cells of the memory array;
a plurality of data ports disposed on one side near the sensor amplifiers; and
a plurality of address ports disposed on another side near the column driver/decoders.

20. The semiconductor device as claimed in claim 19, wherein the column select line sharing structure memory is a dynamic random access memory.
